(19) United States
(12) Patent Application Publication
(10) Pub. No.: US 2025/0236792 A1
(43) Pub. Date: Jul. 24, 2025

(54) ETCHANT COMPOSITION FOR ETCHING SILICON AND METHOD OF FORMING PATTERN USING THE SAME

(71) Applicant: DONGWOO FINE-CHEM CO., LTD., Jeollabuk-do (KR)

(72) Inventors: JIN KYU ROH, Jeollabuk-do (KR); SANG KWON KIM, Jeollabuk-do (KR); KYU SANG AHN, Jeollabuk-do (KR); HYO JOONG YOON, Jeollabuk-do (KR)

(21) Appl. No.: 19/015,964

(22) Filed: Jan. 10, 2025

(30) Foreign Application Priority Data
Jan. 24, 2024 (KR) 10-2024-0010655

(51) Int. Cl. C09K 13/00; H01L 21/02

(52) U.S. Cl. CPC C09K 13/00; H01L 21/02343

(57) ABSTRACT

An etchant composition for etching silicon includes an alkaline compound, a metal salt, a compound including a fused structure of a nitrogen-containing ring to which a polar functional group is bonded and a nitrogen-free ring, and water. A method of forming a pattern includes etching a silicon-containing film using the etchant composition for etching silicon.

### CROSS REFERENCE TO RELATED APPLICATION AND CLAIM OF PRIORITY

This application claims the benefit under 35 USC § 119 of Korean Patent Application No. 10-2024-0010655 filed on Jan. 24, 2024, in the Korean Intellectual Property Office, the entire disclosure of which is incorporated herein by reference for all purposes.

### BACKGROUND

### 1. Field of the Invention

The present disclosure relates to an etchant composition for etching silicon and a method of forming a pattern using the same.

### 2. Description of the Related Art

For example, in a semiconductor device such as a DRAM, NAND FLASH memory device, and logic device, etc., development to implement a large capacity while rapidly reducing a critical dimension (CD) has been continuously conducted.

In the semiconductor device, a film or pattern based on silicon such as polysilicon, for example, is widely used as a material for a gate electrode, capacitor electrode, conductive contact, and line, etc. When forming the gate electrode or line through direct etching of a metal film, it is not easy to form a pattern having desired fine dimensions due to limitations in an etching resolution, and therefore, a process utilizing a polysilicon film is being studied.

In order to perform a semiconductor device process with high reliability, securing a fast etching rate for a subject to be removed and excellent etching uniformity according thereto are required. However, when performing an etching process, an increase in the etching rate for the subject to be removed may promote etching for a protective film.

Accordingly, when performing an etching process of silicon film, development of an etchant composition to improve an etching selectivity while maintaining excellent etching rate and etching uniformity for forming a fine dimensional pattern is required.

### SUMMARY

An object of the present disclosure is to provide an etchant composition for etching silicon having improved etching efficiency.

Another object of the present disclosure is to provide a method of forming a pattern utilizing the etchant composition for etching silicon.

To achieve the above objects, the following technical solutions are adopted in the present disclosure.
1. An etchant composition for etching silicon including: an alkaline compound; a metal salt; a nitrogen-containing fused ring compound which includes a fused structure of a nitrogen-containing ring to which a polar functional group is bonded and a nitrogen-free ring; and water.
2. The etchant composition for etching silicon according to the above 1, wherein the nitrogen-containing fused ring compound has a structure in which a benzene ring and a nitrogen-containing ring including one or two nitrogen atoms are fused.
3. The etchant composition for etching silicon according to the above 1, wherein the polar functional group includes at least one selected from the group consisting of a hydroxyl group, an amine group, an aldehyde group, a carboxyl group, an alkoxy group and a carbonyl group.
4. The etchant composition for etching silicon according to the above 1, wherein the nitrogen-containing fused ring compound includes a quinoline compound or a derivative thereof, or a quinoxaline compound or a derivative thereof.
5. The etchant composition for etching silicon according to the above 1, wherein the nitrogen-containing fused ring compound is represented by Formula 1 below:

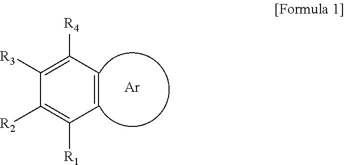

(in Formula 1 above, R₁ to R₄ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
Ar is a heterocyclic ring which includes at least one selected from the group consisting of a hydroxyl group, an amine group, an aldehyde group, a carboxyl group, an alkoxy group and a carbonyl group, and has 1 or 2 nitrogen atoms).
6. The etchant composition for etching silicon according to the above 5, wherein in Formula 1 above, Ar has a structure represented by Formula 2 below:

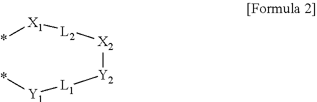

(in Formula 2 above, when L₁ is a direct single bond and Y₁ is NH, Y₂ is a carbonyl group,
when L₁ is a direct double bond and Y₁ is N, Y₂ is C(R₅),
when L₂ is a direct single bond and X₁ is NH or C(R₆R₇), X₂ is a carbonyl group,
when L₂ is a direct double bond and X₁ is N or C(R₈), X₂ is C(R₉),
R₅ and R₉ are each hydrogen, a hydroxyl group, an amine group, an aldehyde group, a carboxyl group, an alkoxy group having 1 to 10 carbon atoms or an alkylcarbonyl group having 2 to 10 carbon atoms,
when Y₂ is C(R₅) and X₂ is C(R₉), one of R₅ and R₉ is hydrogen, a hydroxyl group, an amine group, an aldehyde group, a carboxyl group, an alkoxy group having 1 to 10 carbon atoms or an alkylcarbonyl group having 2 to 10 carbon atoms, and the other is a hydroxyl group, an amine group, an aldehyde group, a carboxyl group, an alkoxy group having 1 to 10 carbon atoms or an alkylcarbonyl group having 2 to 10 carbon atoms, and
R₆ to R₈ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen).
7. The etchant composition for etching silicon according to the above 5, wherein in Formula 1 above, Ar is any one of structures represented by Formulas 3 to 6 below:

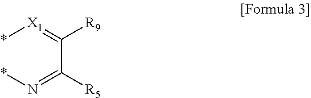

(in Formula 3 above, X₁ is N or C(R₈), R₈ is hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
one of R₅ and R₉ is hydrogen, a hydroxyl group, an amine group, an aldehyde group, a carboxyl group, an alkoxy group having 1 to 10 carbon atoms or an alkylcarbonyl group having 2 to 10 carbon atoms, and the other one is a hydroxyl group, an amine group, an aldehyde group, a carboxyl group, an alkoxy group having 1 to 10 carbon atoms or an alkylcarbonyl group having 2 to 10 carbon atoms)

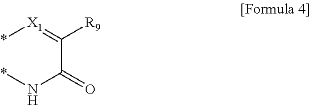

(in Formula 4 above, X₁ is N or C(R₈), R₈ is hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
R₉ is hydrogen, a hydroxyl group, an amine group, an aldehyde group, a carboxyl group, an alkoxy group having 1 to 10 carbon atoms or an alkylcarbonyl group having 2 to 10 carbon atoms)

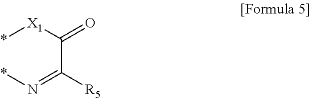

(in Formula 5 above, X₁ is NH or C(R₆R₇), R₆ and R⁷ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
R₅ is hydrogen, hydroxyl group, an amine group, an aldehyde group, a carboxyl group, an alkoxy group having 1 to 10 carbon atoms or an alkylcarbonyl group having 2 to 10 carbon atoms)

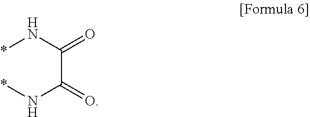 [SMILES: *NC(=O)C(=O)N*]

8. The etchant composition for etching silicon according to the above 1, wherein a content of the nitrogen-containing fused ring compound is 0.01% by weight to 20% by weight based on a total weight of the composition.
9. The etchant composition for etching silicon according to the above 1, wherein a content of the nitrogen-containing fused ring compound is 0.05% by weight to 15% by weight based on a total weight of the composition.
10. The etchant composition for etching silicon according to the above 1, wherein the metal salt includes a salt of at least one metal selected from the group consisting of a transition metal, a post-transition metal and a metalloid.
11. The etchant composition for etching silicon according to the above 1, wherein a content of the metal salt is 0.0001% by weight to 20% by weight based on a total weight of the composition.
12. The etchant composition for etching silicon according to the above 1, wherein the metal salt includes a first metal salt which is a salt of at least one metal selected from the group consisting of a transition metal, a post-transition metal and a metalloid, and a second metal salt which is a salt of an alkali metal or an alkaline earth metal.
13. The etchant composition for etching silicon according to the above 12, wherein a content of the first metal salt is 0.0001% by weight to 10% by weight based on a total weight of the composition, and a content of the second metal salt is 0.001% by weight to 18% by weight based on the total weight of the composition.
14. The etchant composition for etching silicon according to the above 1, wherein a ratio of a content of the metal salt to a content of the nitrogen-containing fused ring compound in a total weight of the composition is 0.0005 to 10.
15. The etchant composition for etching silicon according to the above 1, wherein the alkaline compound includes a nitrogen-based alkaline compound or a metal hydroxide.
16. The etchant composition for etching silicon according to the above 1, wherein a content of the alkaline compound is 0.1% by weight to 20% by weight based on a total weight of the composition.
17. A method of forming a pattern, including: forming a silicon-containing film on a substrate; partially forming a silicon protective film on the silicon-containing film; and etching the silicon-containing film with the etchant composition for etching silicon according to the above 1.
18. The method of forming a pattern according to the above 17, wherein the silicon protective film is used as an etching mask.
19. The method of forming a pattern according to the above 17, wherein the step of etching the silicon-containing film includes etching the silicon-containing film to form a gate pattern.

The etchant composition for etching silicon according to exemplary embodiments of the present invention may etch a silicon oxide film and/or a silicon nitride film less while etching a silicon-containing film at a high speed. Accordingly, the composition may have a high etching selectivity for the silicon-containing film.

The etchant composition for etching silicon according to exemplary embodiments may further include the salt of an alkali metal or an alkaline earth metal. Accordingly, the etching rate for the silicon-containing film may be further increased.

The etchant composition for etching silicon according to exemplary embodiments of the present invention may be used to form a nanoscale semiconductor device pattern with high reliability.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 7 are schematic cross-sectional views illustrating a method of forming a pattern according to exemplary embodiments.

### DETAILED DESCRIPTION OF THE INVENTION

According to exemplary embodiments of the present invention, an etchant composition for etching silicon (hereinafter, may be abbreviated as a composition) including a nitrogen-containing fused ring compound and a metal salt is provided. In addition, a method of forming a pattern using the composition is provided.

Hereinafter, the present disclosure will be described in detail through embodiments with reference to the accompanying drawings. However, the embodiments are merely illustrative and the present disclosure is not limited to the specific embodiments described by way of example.

According to exemplary embodiments, the composition includes an alkaline compound. The alkaline compound includes a hydroxyl group or is dissociated to form a hydroxide ion, and the hydroxyl group or hydroxide ion may act as a silicon etchant.

The alkaline compound may include a nitrogen-based alkaline compound or a metal hydroxide. In some embodiments, the nitrogen-based alkaline compound may be an amine compound, an ammonium compound or the like. These may be used alone or in combination of two or more thereof.

For example, the amine compound may include hydroxyl amine or an organic amine compound.

The organic amine compound may include a hydrocarbon group having 1 to 20 carbon atoms and at least one amine group. For example, the organic amine compound may include an alkylamine compound, an arylamine compound, an alkanolamine compound, a nitrogen-containing cyclic compound different from the nitrogen-containing fused ring compound, etc. For example, the alkylamine compound may include 1,2-diaminopropane, diethylenetriamine, isopropylamine, triethylamine, trimethylamine, methylamine, ethylamine, 2-aminopentane, diethylamine, etc.

For example, the arylamine compound may include aniline, etc.

For example, the alkanolamine compound may include 1-amino-2-propanol, 2-amino-1-butanol, 3-amino-1-propanol, 3-amino-1,2-propanediol, methyldiethanolamine, propanolamine, ethanolamine, diethanolamine, N-methylethanolamine, N-methyldiethanolamine, 2-amino-3-methyl-1-butanol, 3-amino-2,2-dimethyl-1-propanol, tris(hydroxymethyl) aminomethane, 2-amino-2-methyl-1,3-propanediol, 3-methylamino-1-propanol, 2-dimethylamino-2-methyl-1-propanol, 1-dimethylamino-2-propanol, 3-dimethylamino-1-propanol, 2-dimethylamino-1-propanol, 2-diethylamino-1-propanol, 2-diethylamino-1-ethanol, 2-ethylamino-1-ethanol, 1-(dimethylamino) 2-propanol, diethanolamine N-propyldiethanolamine, N-isopropyldiethanolamine, N-(2-methylpropyl) diethanolamine, N-n-butyldiethanolamine, N-t-butylethanolamine, N-cyclohexyldiethanolamine, N-dodecyldiethylamine, 2-(dimethylamino) ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl) ethanolamine, 2-amino-2-methyl-1-propanol, tris(hydroxymethyl) aminomethane, triisopropanolamine, etc.

The nitrogen-containing cyclic compound may include a pyridine compound or an azabicyclo compound.

For example, the pyridine compound may include trimethylpyridine, dimethylpyridine, etc.

The azabicyclo compound may include an azabicyclo structure, a diazabicyclo structure or a triazabicyclo structure. For example, the azabicyclo compound may include a saturated hydrocarbon group such as butane, pentane, hexane, heptane, octane, nonane, decane, undecane, dodecane, tridecane, tetradecane; or an unsaturated hydrocarbon group such as nonene, decene, undecene.

The ammonium compound may include ammonium hydroxide or an organic ammonium compound.

The organic ammonium compound may include a hydrocarbon group having 1 to 20 carbon atoms and at least one ammonium group. For example, the organic ammonium compound may include a tetraalkyl ammonium compound.

For example, the organic ammonium compound may include tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltriethylammonium hydroxide, diethyldimethylammonium hydroxide, methyltributylammonium hydroxide, etc.

For example, the metal hydroxide may include lithium hydroxide, sodium hydroxide, potassium hydroxide, rubidium hydroxide, cesium hydroxide, francium hydroxide, etc.

These may be used alone or in combination of two or more thereof.

A content of the alkaline compound may be 0.1% by weight (“wt %”) to 20 wt % based on a total weight of the composition. In some embodiments, the content of the alkaline compound may be 0.5 wt % to 17 wt %, or 1 wt % to 15 wt % based on the total weight of the composition.

Within the above range, a large amount of the hydroxyl group or hydroxide ions capable of etching silicon may be sufficiently secured, and thereby increasing a silicon etching rate of the composition. In addition, the alkaline compound may not be adsorbed on the surface of an etching object, and may not interfere with silicon etching.

According to exemplary embodiments, the composition includes a metal salt. The metal salt may improve anticorrosion of the composition to a silicon oxide film and/or a silicon nitride film. For example, the metal salt may form an organo-metallic complex with a nitrogen-containing fused ring compound to be described below. The organo-metallic complex may bond to a —Si—X—(wherein X is oxygen or nitrogen) structure exposed to the surface of the silicon oxide film and/or the silicon nitride film to form a protective layer. Accordingly, the protective layer may protect the silicon oxide film and/or the silicon nitride film so that they are not exposed to an etchant, and the anticorrosion of the composition may be improved.

According to exemplary embodiments, the metal salt may include a salt of at least one metal selected from the group consisting of a transition metal, a post-transition metal and a metalloid.

For example, the transition metal may include titanium (Ti), vanadium (V), chromium (Cr), manganese (Mn), cobalt (Co), iron (Fe), nickel (Ni), copper (Cu), zinc (Zn), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), etc.

For example, the post-transition metal may include aluminum (Al), gallium (Ga), indium (In), tin (Sn), thallium (TI), lead (Pb), bismuth (Bi), etc.

For example, the metalloid may include silicon (Si), germanium (Ge), polonium (Po), etc.

For example, the metal salt may be a compound in which a metal cation and an inorganic or organic anion are ionically bonded. The metal cation may be a cation of the above-described transition metal, post-transition metal and/or metalloid.

For example, the inorganic anion may include oxide, chloride, bromine, iodine, nitrite, nitrate, sulfate, sulfide, phosphate, phosphite, perchlorate, boride, etc.

For example, the organic anion may include alkoxide, acetate, isopropoxide, acetylacetonate, fluoromethane sulfonate, carbide, phenoxide, carbonate, etc.

These may be used alone or in combination of two or more thereof.

A content of the metal salt may be 0.0001 wt % to 20 wt % based on the total weight of the composition. In some embodiments, the content of the metal salt may be 0.001 wt % to 17.5 wt % based on the total weight of the composition. Within the above range, anticorrosion effects for the silicon oxide film and the silicon nitride film may be improved.

In exemplary embodiments, the metal salt may include a first metal salt, which is a salt of at least one metal selected from the group consisting of a transition metal, a post-transition metal and a metalloid, and a second metal salt, which is a salt of an alkali metal or an alkaline earth metal. The first metal salt may be the same as those described above, and the second metal salt may be a salt of the alkali metal or alkaline earth metal.

The second metal salt may improve the structural stability of the organo-metal complex, thereby stabilizing the protective layer on the surface of the silicon oxide film and/or the silicon nitride film and improving the anticorrosion effect of the composition.

For example, the alkali metal may include lithium (Li), sodium (Na), potassium (K), rubidium (Rb), cesium (Cs), francium (Fr), etc.

For example, the alkaline earth metal may include beryllium (Be), magnesium (Mg), calcium (Ca), strontium (Sr), barium (Ba), radium (Ra), etc.

The second metal salt may be a compound in which a cation of an alkali metal or an alkaline earth metal and an inorganic or organic anion are ionically bonded. The inorganic or organic anion may be the same as those described above.

A content of the first metal salt may be 0.0001 wt % to 10 wt % based on the total weight of the composition. In some embodiments, the content of the first metal salt may be 0.0001 wt % to 10 wt %, or 0.001 wt % to 5 wt % based on the total weight of the composition. Within the above range, the anticorrosion effects for the silicon oxide film and the silicon nitride film may be further improved.

A content of the second metal salt may be 0.001 wt % to 18 wt % based on the total weight of the composition. In some embodiments, the content of the second metal salt may be 0.001 wt % to 15 wt %. Within the above range, the etching rate of the composition for silicon may be maintained high, as well as the anticorrosion effects for the silicon oxide film and the silicon nitride film may be improved.

According to exemplary embodiments, the composition includes a nitrogen-containing fused ring compound. The nitrogen-containing fused ring compound includes a nitrogen-containing ring to which a polar functional group is bonded and a nitrogen-free ring, and the nitrogen-containing ring and the nitrogen-free ring may have a fused structure.

The nitrogen-containing ring and the nitrogen-free ring may share two atoms. For example, the nitrogen-containing ring and the nitrogen-free ring may share two carbon atoms.

The nitrogen-containing ring may include one or two nitrogen atoms, and the nitrogen-free ring may be a benzene ring. For example, the nitrogen-containing fused ring compound may include a quinoline compound or a derivative thereof, or a quinoxaline compound or a derivative thereof.

As used herein, the term “derivative” of the compound may mean a compound in which a functional group is introduced into the compound, or oxidized or reduced, or otherwise, some atoms are substituted and changed within the range of maintaining the properties of the compound.

A polar functional group may be bonded to the nitrogen-containing ring. For example, the polar functional group may include a hydroxyl group, an amine group, an aldehyde group, a carboxyl group, an alkoxy group, a carbonyl group, etc. These may be used alone or in combination of two or more thereof.

The carbonyl group may form a portion of the nitrogen-containing ring, or may be bonded to the nitrogen-containing ring in the form of an alkylcarbonyl group.

The polar functional group may be oxidized in an alkaline atmosphere of the composition, for example, the aldehyde group or carboxyl group may be oxidized to a hydroxyl group, the carbonyl group forming a portion of the nitrogen-containing ring may be oxidized to the hydroxyl group, and the carbonyl group bonded to the nitrogen-containing ring in the form of an alkylcarbonyl group may be oxidized to a hydroxymethyl group bonded to the nitrogen-containing ring.

The polar functional group may include nitrogen or oxygen, thus to form an electron-rich environment around the nitrogen-containing ring. Accordingly, the metal salt may be bonded to a nitrogen atom to easily form an organo-metal complex.

When the nitrogen-containing ring does not have a polar functional group, it is difficult for the metal salt to strongly bond with the nitrogen atom, and thereby a protective layer on the surface of the silicon oxide film and/or the silicon nitride film may not be formed or may be formed less firmly. Accordingly, the anticorrosion effects of the composition for the silicon oxide film and/or the silicon nitride film may be reduced.

According to exemplary embodiments, the quinoline compound may have a polar functional group bonded to carbons at positions 2, 3 and/or 4, and the quinoxaline compound may have a polar functional group bonded to carbons at positions 2 and/or 3.

According to exemplary embodiments, the derivative of the quinoline compound may include a quinolinone compound, and the derivative of the quinoxaline compound may include a quinoxalinone compound. For example, in the nitrogen-containing ring of the quinoline compound or quinoxaline compound, double-bonded carbons at positions 2, 3 and/or 4 may be single-bonded with nitrogen or carbon from the double bond, and may be double-bonded with oxygen to form a carbonyl group.

According to exemplary embodiments, the nitrogen-containing fused ring compound may be represented by Formula 1 below:

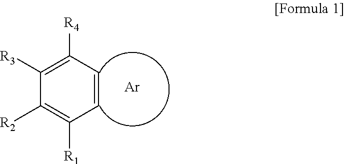

In Formula 1 above, R₁ to R₄ may each independently be hydrogen, a substituent, or an alkyl group having 1 to 10 carbon atoms with or without the substituent.

The substituent may be a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group, halogen, etc.

The alkylcarbonyl group is a carbonyl group to which an alkyl group is bonded, and the alkylcarbonyl group having 2 to 10 carbon atoms may be a carbonyl group to which an alkyl group having 1 to 9 carbon atoms is bonded.

For example, R₁ to R₄ may each independently be hydrogen, a hydroxyl group, halogen, a methoxy group, a methyl group, a carboxyl group, a nitric acid group, or an alkyl group which includes a carboxyl group and an amine group and has 1 to 3 carbon atoms.

In Formula 1 above, Ar may be a nitrogen-containing ring. The Ar may be a heterocyclic ring which includes at least one selected from the group consisting of a hydroxyl group, an amine group, an aldehyde group, a carboxyl group, an alkoxy group and a carbonyl group, and has 1 or 2 nitrogen atoms.

According to exemplary embodiments, in Formula 1, Ar may have a structure represented by Formula 2 below.

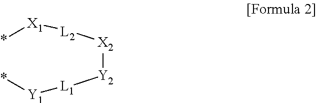

In Formula 2 above, L₁ may be a direct single bond or a direct double bond. For example, when L₁ is a direct single bond and Y₁ is NH, Y₂ may be a carbonyl group, and when L₁ is a direct double bond and Y₁ is N, Y₂ may be C(R₅).

In Formula 2 above, L₂ may be a direct single bond or a direct double bond.

When L₂ is a direct single bond and X₁ is NH or C(R₆R₇), X₂ is a carbonyl group, and when L₂ is a direct double bond and X₁ is N or C(R₈), X₂ may be C(R₉).

In Formula 2 above, R₅ and R₉ may each be hydrogen or a polar functional group. The polar functional group may include a hydroxyl group, an amine group, an aldehyde group, a carboxyl group, an alkoxy group having 1 to 10 carbon atoms, and an alkylcarbonyl group having 2 to 10 carbon atoms.

When at least one of L₁ and L₂ is a single bond, R₅ and R₉ may each independently be hydrogen or a polar functional group.

In some embodiments, when Y₂ is C(R₅) and X₂ is C(R₉), one of R₅ and R₉ may be hydrogen or a polar functional group, and the other may be a polar functional group. At least one of R₈ and R₉ may be a polar functional group, and if R₈ and R₉ are the same as each other, R₅ and R₉ may not be hydrogen.

In some embodiments, at least one of R₅ and R₉ may be a hydroxyl group, an amine group, an aldehyde group, a carboxyl group, a methoxy group or an acetyl group.

In Formula 2 above, R₆ to R₈ may each independently be hydrogen, a substituent, or an alkyl group having 1 to 10 carbon atoms with or without the substituent.

The substituent may be a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group, halogen, etc.

According to exemplary embodiments, in Formula 1 above, Ar may have a structure represented by Formula 3 below.

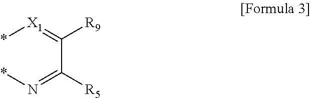

In Formula 3 above, X₁ may be N or C(R₈), and R₈ may be hydrogen, a substituent, or an alkyl group having 1 to 10 carbon atoms with or without the substituent.

The substituent may be a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group, halogen, etc.

In Formula 3 above, one of R₅ and R₉ may be hydrogen, a hydroxyl group, an amine group, an aldehyde group, a carboxyl group, an alkoxy group having 1 to 10 carbon atoms or an alkylcarbonyl group having 2 to 10 carbon atoms, and the other may be a hydroxyl group, an amine group, an aldehyde group, a carboxyl group, an alkoxy group having 1 to 10 carbon atoms or an alkylcarbonyl group having 2 to 10 carbon atoms.

According to exemplary embodiments, in Formula 1 above, Ar may have a structure represented by Formula 4 below.

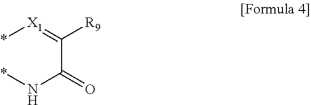

In Formula 4 above, X₁ is N or C(R₈), and R₈ may be hydrogen, a substituent, or an alkyl group having 1 to 10 carbon atoms with or without the substituent.

The substituent may be a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group, halogen, etc.

In Formula 4 above, R₉ may be hydrogen, a hydroxyl group, an amine group, an aldehyde group, a carboxyl group, an alkoxy group having 1 to 10 carbon atoms or an alkylcarbonyl group having 2 to 10 carbon atoms.

According to exemplary embodiments, in Formula 1 above, Ar may have a structure represented by Formula 5 below.

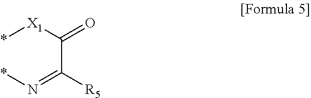

In Formula 5 above, X₁ may be NH or C(R₆R₇), and R₆ and R⁷ may each independently be hydrogen, a substituent, or an alkyl group having 1 to 10 carbon atoms with or without the substituent.

The substituent may be a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group, halogen, etc.

In Formula 5 above, R₅ may be hydrogen, a hydroxyl group, an amine group, an aldehyde group, a carboxyl group, an alkoxy group having 1 to 10 carbon atoms or an alkylcarbonyl group having 2 to 10 carbon atoms.

According to exemplary embodiments, in Formula 1 above, Ar may have a structure represented by Formula 6 below.

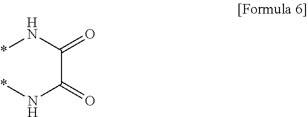 [SMILES: *NC(=O)C(=O)N*]

For example, the nitrogen-containing fused ring compound may include 2-hydroxyquinoline, 3-aminoquinoline, 2-quinolinecarboxaldehyde, 6-chloro-2-hydroxyquinoline, 2,4-quinolinediol, 2,8-quinolinediol, 6-fluoroquinoline-2-carboxaldehyde, 2-hydroxy-4 methylquinoline, quinaldic acid, 8-chloro-2-hydroxyquinoline, 8-hydroxy-2-quinolinecarboxaldehyde, 4-methoxy-2 (1H)-quinolinone, 4,6,7-trimethoxy-2 (1H)-quinolinone, 8-hydroxy-2-quinolinecarboxylic acid, 4-hydroxyquinoline-2-carboxylic acid, 8-fluoroquinoline-2-carboxylic acid, 2-hydroxyquinoline-4-carboxylic acid, 2-ethoxyquinoline-3-carbaldehyde, 2-methoxy-quinoline-4-carboxylic acid, 3-(2-oxo-1,2-dihydro-4-quinolinyl) alanine hydrochloride monohydrate, 2-quinoxalinol, 2,3-dihydroxyquinoxaline, 2-quinoxalinecarbaldehyde, 1,4-dihydro-6-methylquinoxaline-2,3-dione, 2-acetylquinoxaline, 2-quinoxalinecarboxylic acid, 6-nitro-2,3-dihydroxyquinoxaline, 2,3-dioxo-1,2,3,4-tetrahydroquinoxaline-6-carboxylic acid, 3-hydroxy-2-quinoxalinecarboxylic acid, 6,7-dinitroquinoxaline-2,3 (1H,4H)-dione, etc. These may be used alone or in combination of two or more thereof.

A content of the nitrogen-containing fused ring compound may be 0.01 wt % to 20 wt % based on the total weight of the composition, and in some embodiments, may be 0.05 wt % to 15 wt %, or 0.1 wt % to 10 wt % based on the total weight of the composition. Within the above range, the silicon etching rate of the composition may be further improved.

According to exemplary embodiments, a ratio of the content of the metal salt to the content of the nitrogen-containing fused ring compound in the total weight of the composition may be 0.0005 to 10. According to some embodiments, the ratio of the content of the metal salt to the content of the nitrogen-containing fused ring compound in the total weight of the composition may be 0.00067 to 5. Within the above range, the content ratio of the nitrogen-containing fused ring compound forming the organo-metal complex and the metal salt is appropriate, such that the protective films of the silicon oxide film and the silicon nitride film may be firmly formed.

The composition includes water. The water may be a medium in which the alkaline compound, the metal salt and the nitrogen-containing fused ring compound are dissolved or dispersed.

A content of the water may be the balance except for the contents of the alkaline compound, the metal salt and the nitrogen-containing fused ring compound in the total weight of the composition. For example, the content of water may be 65 wt % to 98.5 wt %, or 67.99 wt % to 98.49 wt % based on the total weight of the composition.

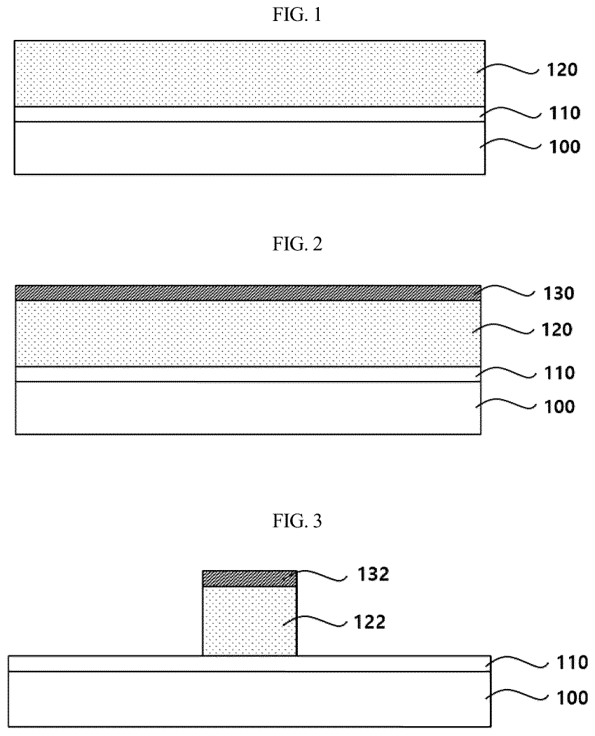

FIGS. 1 to 7 are schematic cross-sectional views for describing a method of forming a pattern according to exemplary embodiments.

However, the etchant composition according to exemplary embodiments is not limited to the processes of FIGS. 1 to 7, and may be utilized in various processes for forming structures or patterns such as lines, contacts, and gates, etc., as long as they are included in the spirit and technical scope of the present invention.

FIGS. 1 to 3 are schematic cross-sectional views for describing a method of manufacturing a semiconductor device according to exemplary embodiments.

Referring to FIG. 1, an insulation film 110 may be formed on a substrate 100, and a silicon-containing film 120 may be formed on the insulation film 110.

The substrate 100 may include a semiconductor material such as single crystal silicon, single crystal germanium, and may include polysilicon.

The insulation film 110 may be formed to include an insulation material such as silicon oxide, silicon nitride, silicon oxynitride, polysiloxane, etc. For example, the insulation film 110 may be formed through a chemical vapor deposition (CVD) process, a sputtering process, a physical vapor deposition (PVD) process, an atomic layer deposition (ALD) process, etc.

The silicon-containing film 120 may include single crystal silicon, polysilicon, or amorphous silicon.

Referring to FIG. 2, a silicon protective film 130 may be formed on the silicon-containing film 120. The silicon protective film 130 may be formed to include a silicon oxide film or a silicon nitride film. For example, the silicon protective film 130 may be formed through the CVD process, the sputtering process, the PVD process, the ALD process, etc.

The silicon protective film 130 may be used as an etching mask.

The silicon protective film 130 may be partially etched to form a mask pattern 132. For example, a portion of the silicon protective film 130 may be partially etched until a portion of an upper surface of the silicon-containing film 120 is exposed.

Referring to FIG. 3, the silicon-containing film 120 may be partially removed using the above-described etchant composition according to the exemplary embodiments. Accordingly, a gate pattern 122 may be formed from the silicon-containing film 120.

As described above, the etchant composition includes a basic compound and an inorganic fluoride compound, such that the etching efficiency for silicon and the anticorrosion effect for the silicon protective film may be improved. Accordingly, only the silicon-containing film 120 may be selectively etched while effectively preventing the etching for the mask pattern 132 to form the gate pattern 122 with high reliability.

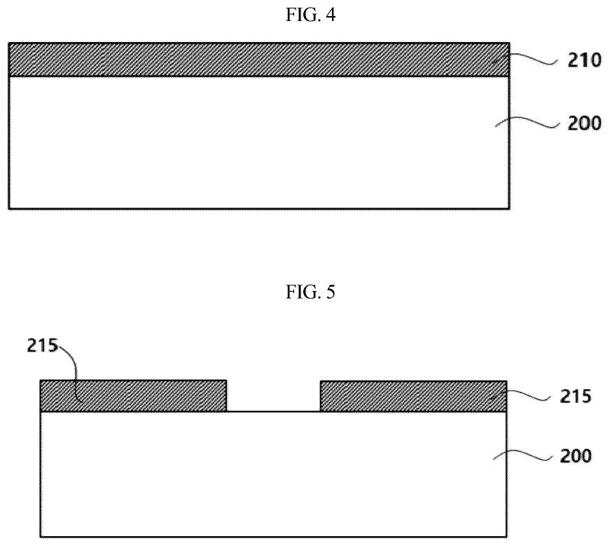

FIG. 4 to FIG. 7 are schematic cross-sectional views for describing a method of forming a pattern according to exemplary embodiments. Specifically, FIG. 4 to FIG. 7 are schematic cross-sectional views for describing a method of forming a shallow trench isolation (STI) according to exemplary embodiments.

Referring to FIG. 4, a silicon protective film 210 may be formed on a substrate 200.

The substrate 200 may be a silicon substrate including single crystal silicon, polysilicon, or amorphous silicon.

The silicon protective film 210 may include a silicon oxide film or a silicon nitride film. In this case, the silicon protective film may be formed by the chemical vapor deposition (CVD) process, the sputtering process, the physical vapor deposition (PVD) process, the atomic layer deposition (ALD) process, etc., to cover an upper surface of the substrate 200.

Referring to FIG. 5, the silicon protective film 210 may be partially etched to form a mask pattern 215. For example, a portion of the silicon protective film 210 may be etched until a portion of the upper surface of the substrate 200 is exposed.

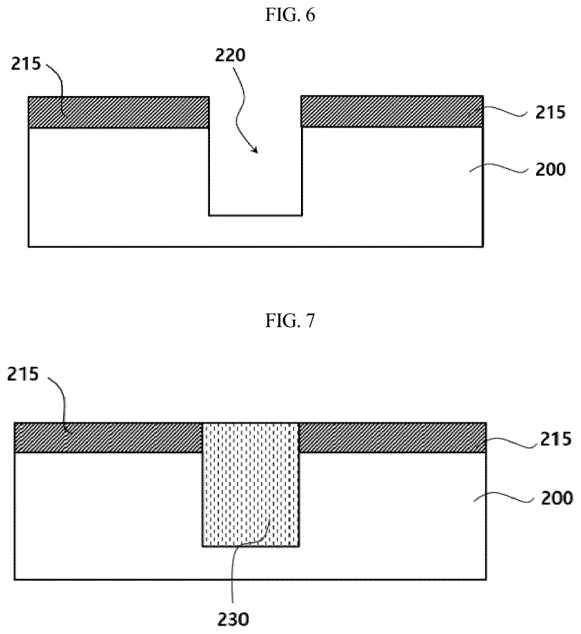

Referring to FIG. 6, the upper portion of the substrate 200 may be partially etched using the above-described etchant composition according to the exemplary embodiments. Accordingly, a trench 220 may be formed inside the substrate 200.

As described above, the etchant composition may be used to selectively etch only the upper portion of the substrate 200 while preventing the etching for the mask pattern 215. Therefore, for example, in a nanoscale micro-etching process, the upper portion of the substrate 200 may be removed without etching defects, and a highly reliable etching process may be performed.

Referring to FIG. 7, an insulation pattern 230 may be formed inside the trench 220.

The insulation pattern 230 may be formed to include an insulation material including silicon oxide, silicon nitride, silicon oxynitride or polysiloxane. For example, the insulation material may be formed through the CVD process, the sputtering process, the PVD process, the ALD process, etc. to fill the inside of the trench 220.

Hereinafter, embodiments of the present invention will be further described with reference to specific experimental examples. However, the following examples and comparative examples included in the experimental examples are only given for illustrating the present invention and those skilled in the art will obviously understand that various alterations and modifications are possible within the scope and spirit of the present invention. Such alterations and modifications are duly included in the appended claims.

### Examples and Comparative Examples

Etchant compositions for etching silicon were prepared with the composition described in Table 1 and Table 2 below. The content of each component was expressed as wt % based on the total weight of the composition, and preparation was performed by adding water as the balance so that the content of the composition was 100 wt %.

TABLE 1

| Composition | (A) | | (B) | | (C) | | (D) | | |
|---|---|---|---|---|---|---|---|---|---|
| (wt %) | Type | Content | Type | Content | Type | Content | Type | Content | Water |
| Example 1 | A-1 | 0.5 | B-1 | 0.01 | C-1 | 1 | — | — | Balance |
| Example 2 | A-1 | 1 | B-1 | 0.01 | C-1 | 1 | — | — | Balance |
| Example 3 | A-1 | 5 | B-1 | 0.01 | C-1 | 1 | — | — | Balance |
| Example 4 | A-1 | 10 | B-1 | 0.01 | C-1 | 1 | — | — | Balance |
| Example 5 | A-1 | 15 | B-1 | 0.01 | C-1 | 1 | — | — | Balance |
| Example 6 | A-1 | 17 | B-1 | 0.01 | C-1 | 1 | — | — | Balance |
| Example 7 | A-2 | 10 | B-1 | 0.01 | C-1 | 1 | — | — | Balance |
| Example 8 | A-3 | 10 | B-1 | 0.01 | C-1 | 1 | — | — | Balance |
| Example 9 | A-1 | 10 | B-1 | 0.00001 | C-1 | 1 | — | — | Balance |
| Example 10 | A-1 | 10 | B-1 | 0.0001 | C-1 | 1 | — | — | Balance |
| Example 11 | A-1 | 10 | B-1 | 0.001 | C-1 | 1 | — | — | Balance |
| Example 12 | A-1 | 10 | B-1 | 0.01 | C-1 | 1 | — | — | Balance |
| Example 13 | A-1 | 10 | B-1 | 1 | C-1 | 1 | — | — | Balance |
| Example 14 | A-1 | 10 | B-1 | 5 | C-1 | 1 | — | — | Balance |
| Example 15 | A-1 | 10 | B-1 | 10 | C-1 | 1 | — | — | Balance |
| Example 16 | A-1 | 10 | B-1 | 12 | C-1 | 1 | — | — | Balance |
| Example 17 | A-1 | 10 | B-2 | 0.01 | C-1 | 1 | — | — | Balance |
| Example 18 | A-1 | 10 | B-3 | 0.01 | C-1 | 1 | — | — | Balance |
| Example 19 | A-1 | 10 | B-1 | 0.01 | C-1 | 0.005 | — | — | Balance |
| Example 20 | A-1 | 10 | B-1 | 0.01 | C-1 | 0.01 | — | — | Balance |
| Example 21 | A-1 | 10 | B-1 | 0.01 | C-1 | 0.1 | — | — | Balance |
| Example 22 | A-1 | 10 | B-1 | 0.01 | C-1 | 5 | — | — | Balance |
| Example 23 | A-1 | 10 | B-1 | 0.01 | C-1 | 10 | — | — | Balance |
| Example 24 | A-1 | 10 | B-1 | 0.01 | C-1 | 15 | — | — | Balance |
| Example 25 | A-1 | 10 | B-1 | 0.01 | C-1 | 20 | — | — | Balance |
| Example 26 | A-1 | 10 | B-1 | 0.01 | C-1 | 22 | — | — | Balance |
| Example 27 | A-1 | 10 | B-1 | 0.01 | C-2 | 1 | — | — | Balance |
| Example 28 | A-1 | 10 | B-1 | 0.01 | C-3 | 1 | — | — | Balance |
| Example 29 | A-1 | 10 | B-1 | 0.01 | C-1 | 1 | D-1 | 0.001 | Balance |
| Example 30 | A-1 | 10 | B-1 | 0.01 | C-1 | 1 | D-1 | 0.01 | Balance |
| Example 31 | A-1 | 10 | B-1 | 0.01 | C-1 | 1 | D-1 | 0.1 | Balance |
| Example 32 | A-1 | 10 | B-1 | 0.01 | C-1 | 1 | D-1 | 1 | Balance |
| Example 33 | A-1 | 10 | B-1 | 0.01 | C-1 | 1 | D-1 | 5 | Balance |
| Example 34 | A-1 | 10 | B-1 | 0.01 | C-1 | 1 | D-1 | 10 | Balance |
| Example 35 | A-1 | 10 | B-1 | 0.01 | C-1 | 1 | D-1 | 15 | Balance |
| Example 36 | A-1 | 10 | B-1 | 0.01 | C-1 | 1 | D-1 | 17 | Balance |
| Example 37 | A-1 | 10 | B-1 | 0.01 | C-1 | 1 | D-2 | 0.01 | Balance |
| Example 38 | A-1 | 10 | B-1 | 0.01 | C-4 | 1 | — | — | Balance |
| Example 39 | A-1 | 10 | B-1 | 0.01 | C-5 | 1 | — | — | Balance |

TABLE 2

| Composition | (A) | | (B) | | (C) | | (D) | | |
|---|---|---|---|---|---|---|---|---|---|
| (wt %) | Type | Content | Type | Content | Type | Content | Type | Content | Water |
| Comparative | A-1 | 10 | B-1 | 0.01 | C-6 | 1 | D-1 | 0.01 | Balance |
| Example 1 | | | | | | | | | |
| Comparative | A-1 | 10 | B-1 | 0.01 | C-7 | 1 | D-1 | 0.01 | Balance |
| Example 2 | | | | | | | | | |
| Comparative | A-1 | 10 | B-1 | 0.01 | C-8 | 1 | D-1 | 0.01 | Balance |
| Example 3 | | | | | | | | | |
| Comparative | A-1 | 10 | B-1 | 0.01 | C-9 | 1 | D-1 | 0.01 | Balance |
| Example 4 | | | | | | | | | |
| Comparative | A-1 | 10 | B-1 | 0.0001 | — | — | — | — | Balance |
| Example 5 | | | | | | | | | |
| Comparative | A-1 | 10 | B-1 | 0.001 | — | — | — | — | Balance |
| Example 6 | | | | | | | | | |
| Comparative | A-1 | 10 | B-1 | 0.01 | — | — | — | — | Balance |
| Example 7 | | | | | | | | | |
| Comparative | A-1 | 10 | — | — | C-1 | 1 | — | — | Balance |
| Example 8 | | | | | | | | | |
| Comparative | A-1 | 10 | — | — | C-1 | 1 | D-1 | 0.01 | Balance |
| Example 9 | | | | | | | | | |
| Comparative | A-1 | 10 | B-1 | 0.01 | — | — | D-1 | 0.01 | Balance |
| Example 10 | | | | | | | | | |
| Comparative | A-1 | 10 | — | — | — | — | — | — | Balance |
| Example 11 | | | | | | | | | |
| Comparative | A-1 | 10 | — | — | — | — | D-1 | 0.01 | Balance |
| Example 12 | | | | | | | | | |
| Comparative | — | — | B-1 | 0.01 | C-1 | 1 | — | — | Balance |
| Example 13 | | | | | | | | | |
| Comparative | — | — | B-1 | 0.01 | C-1 | 1 | D-1 | 0.01 | Balance |
| Example 14 | | | | | | | | | |
| Comparative | — | — | B-1 | 0.01 | — | — | — | — | Balance |
| Example 15 | | | | | | | | | |
| Comparative | — | — | B-1 | 0.01 | — | — | D-1 | 0.01 | Balance |
| Example 16 | | | | | | | | | |
| Comparative | — | — | — | — | C-1 | 1 | — | — | Balance |
| Example 17 | | | | | | | | | |
| Comparative | — | — | — | — | C-1 | 1 | D-1 | 0.01 | Balance |
| Example 18 | | | | | | | | | |
| Comparative | — | — | — | — | — | — | D-1 | 0.01 | Balance |
| Example 19 | | | | | | | | | |

(A) Alkaline compound
A-1: Tetramethylammonium hydroxide
A-2: Potassium hydroxide
A-3:1,8-Diazabicyclo [5.4.0]undec-7-ene
(B) First metal salt
B-1: Aluminum nitrate
B-2: Iron (III) chloride
B-3: Germanium nitrate
(C) Nitrogen-containing compound
C-1:2-hydroxyquinoxaline
C-2:2,3-dihydroxyquinoxaline
C-3:3-aminoquinoline
C-4:6-chloro-2-hydroxyquinoline
C-5:6-fluoroquinoline-2-carboxaldehyde
C-6:8-methyl-5-quinolinol
C-7:6-hydroxyquinoline
C-8:2-hydroxypyridine
C-9: Monoisopropanolamine
(D) Second metal salt
D-1: Sodium chloride
D-2: Calcium nitrate

### Experimental Example

### (1) Evaluation of Silicon Etching Rate

A silicon wafer was cut into a size of 1.5 cm×1.5 cm to prepare specimens. The specimens were immersed in the etchant compositions of each of the examples and comparative examples under 80° C. condition for 1 minute while stirring at 400 rpm. Then, the specimens were taken out, washed with water, followed by drying in the air, to measure thicknesses of the silicon films using an ellipsometer, then, etching rates of the silicon films were calculated based on change values in the film thickness. At this time, the etching rate was evaluated based on the following standards, and results thereof are shown in Tables 3 and 4 below.

### <Standards for Evaluation>

⊚: Etching rate is 8000 Å/min or more
o: Etching rate is 6000 Å/min or more and less than 8000 Å/min
Δ: Etching rate is 4000 Å/min or more and less than 6000 Å/min
X: Etching rate is 4000 Å/min or less

### (2) Evaluation of Silicon Oxide Film and Nitride Film Anticorrosion Performance

Silicon oxide film and silicon nitride film wafers were cut into a size of 1.5 cm×1.5 cm to prepare specimens. The specimens were immersed in the etchant compositions of each of the examples and comparative examples at 80° C. for 1 minute while stirring at 400 rpm. Then, the specimens were taken out, washed with water, followed by drying in the air, to measure film thicknesses of the silicon oxide films or the silicon nitride films using an ellipsometer, then etching rates were calculated based on change values in the film thickness. In order to quantitatively compare amounts of reduction in the etching rate (“etching rate reduction amounts”), the etching rate reduction amount calculated according to Equation 1 below was evaluated based on the following standards, and results thereof are shown in Tables 3 and 4 below.

$$Etching rate reduction amount ( \% ) = 100 \times ( B - A ) / A \qquad [ Equation 1 ]$$

In Equation 1, A is the etching rate measured using a composition prepared by adding water instead of component (C) in Tables 1 and 2, and B is the etching rate measured using the composition of each of the examples and comparative examples.

### <Standards for Evaluation>

⊚⊚: Reduction rate is greater than 90%:
⊚: Reduction rate is greater than 80% and 90% or less
o: Reduction rate is greater than 60% and less than 80%
Δ: Reduction rate is greater than 40% and less than 60%
X: Reduction rate is greater than 0 to 40%
XX: Reduction rate is 0 (excluding component (C))

TABLE 3

| | Silicon etching | Silicon oxide film | Silicon nitride film |
|---|---|---|---|
| | rate | anticorrosion | anticorrosion |
| Example 1 | Δ | ⊚ | ⊚ |
| Example 2 | ⊚ | ⊚ | ⊚ |
| Example 3 | ⊚ | ⊚ | ⊚ |
| Example 4 | ⊚ | ⊚ | ⊚ |
| Example 5 | ⊚ | ⊚ | ⊚ |
| Example 6 | Δ | ◯ | ◯ |
| Example 7 | ⊚ | ⊚⊚ | ⊚⊚ |
| Example 8 | ⊚ | ⊚ | ⊚ |
| Example 9 | ⊚ | Δ | Δ |
| Example 10 | ⊚ | ◯ | ◯ |
| Example 11 | ⊚ | ⊚ | ⊚ |
| Example 12 | ⊚ | ⊚ | ⊚ |
| Example 13 | ⊚ | ⊚ | ⊚ |
| Example 14 | ⊚ | ⊚ | ⊚ |
| Example 15 | ◯ | ⊚ | ⊚ |
| Example 16 | Δ | ⊚ | ⊚ |
| Example 17 | ⊚ | ⊚ | ⊚ |
| Example 18 | ⊚ | ⊚ | ⊚ |
| Example 19 | ⊚ | Δ | Δ |
| Example 20 | ⊚ | ◯ | ◯ |
| Example 21 | ⊚ | ⊚ | ⊚ |
| Example 22 | ⊚ | ⊚ | ⊚ |
| Example 23 | ⊚ | ⊚ | ⊚ |
| Example 24 | ◯ | ⊚ | ⊚ |
| Example 25 | ◯ | ⊚ | ⊚ |
| Example 26 | Δ | ⊚ | ⊚ |
| Example 27 | ⊚ | ⊚ | ⊚ |
| Example 28 | ⊚ | ⊚ | ⊚ |
| Example 29 | ⊚ | ⊚⊚ | ⊚⊚ |
| Example 30 | ⊚ | ⊚⊚ | ⊚⊚ |
| Example 31 | ⊚ | ⊚⊚ | ⊚⊚ |
| Example 32 | ⊚ | ⊚⊚ | ⊚⊚ |
| Example 33 | ⊚ | ⊚⊚ | ⊚⊚ |
| Example 34 | ⊚ | ⊚⊚ | ⊚⊚ |
| Example 35 | ⊚ | ⊚⊚ | ⊚⊚ |
| Example 36 | Δ | ⊚⊚ | ⊚⊚ |
| Example 37 | ⊚ | ⊚⊚ | ⊚⊚ |
| Example 38 | ⊚ | ⊚ | ⊚ |
| Example 39 | ⊚ | ⊚ | ⊚ |

TABLE 4

| | Silicon etching | Silicon oxide film | Silicon nitride film |
|---|---|---|---|
| | rate | anticorrosion | anticorrosion |
| Comparative | ⊚ | X | X |
| Example 1 | | | |
| Comparative | ⊚ | X | X |
| Example 2 | | | |
| Comparative | ⊚ | X | X |
| Example 3 | | | |
| Comparative | ⊚ | X | X |
| Example 4 | | | |
| Comparative | ⊚ | XX | XX |
| Example 5 | | | |
| Comparative | ⊚ | XX | XX |
| Example 6 | | | |
| Comparative | ⊚ | XX | XX |
| Example 7 | | | |
| Comparative | ⊚ | XX | XX |
| Example 8 | | | |
| Comparative | ⊚ | XX | XX |
| Example 9 | | | |
| Comparative | ⊚ | XX | XX |
| Example 10 | | | |
| Comparative | ⊚ | XX | XX |
| Example 11 | | | |
| Comparative | ⊚ | XX | XX |
| Example 12 | | | |
| Comparative | X | ⊚⊚ | ⊚⊚ |
| Example 13 | | | |
| Comparative | X | ⊚⊚ | ⊚⊚ |
| Example 14 | | | |
| Comparative | X | XX | XX |
| Example 15 | | | |
| Comparative | X | XX | XX |
| Example 16 | | | |
| Comparative | X | ⊚⊚ | ⊚⊚ |
| Example 17 | | | |
| Comparative | X | ⊚⊚ | ⊚⊚ |
| Example 18 | | | |
| Comparative | X | XX | XX |
| Example 19 | | | |

Referring to Table 3 above, the compositions of the examples were had improved anticorrosion effects for the silicon oxide film and the silicon nitride film, while capable of etching silicon at a high rate.

In particular, the compositions of Examples 29 to 37 further including a second metal salt, which is a salt of an alkali metal or an alkaline earth metal, had even more improved anticorrosion for the silicon oxide film and silicon nitride film.

Referring to Table 4 above, since the etching rate for silicon was too slow, or the anticorrosion properties of the compositions of the comparative examples for silicon oxide films and silicon nitride films were decreased, the compositions of the comparative examples were not suitable as etchant composition for etching silicon.

In particular, the compositions of Comparative Examples 1 to 4 did not include the nitrogen-containing fused ring compound or included a nitrogen-containing fused ring compound having a nitrogen-containing ring to which a polar functional group was not bonded.

Accordingly, additional anticorrosion effect effects for the silicon oxide film and the silicon silicide film were not implemented at all.

The contents described above are merely an example of applying the principle of the present disclosure, and other configurations may be further included without departing from the scope of the present invention.

What is claimed is:

1. An etchant composition for etching silicon, comprising:
an alkaline compound;
a metal salt;
a nitrogen-containing fused ring compound comprising a fused structure of a nitrogen-containing ring to which a polar functional group is bonded and a nitrogen-free ring; and
water.

2. The etchant composition according to claim 1, wherein the nitrogen-containing fused ring compound has a structure in which a benzene ring and a nitrogen-containing ring comprising one or two nitrogen atoms are fused.

3. The etchant composition according to claim 1, wherein the polar functional group comprises at least one selected from the group consisting of a hydroxyl group, an amine group, an aldehyde group, a carboxyl group, an alkoxy group and a carbonyl group.

4. The etchant composition according to claim 1, wherein the nitrogen-containing fused ring compound comprises a quinoline compound or a derivative thereof, or a quinoxaline compound or a derivative thereof.

5. The etchant composition according to claim 1, wherein the nitrogen-containing fused ring compound is represented by Formula 1 below: 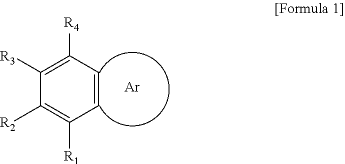
(in Formula 1 above, R₁ to R₄ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
Ar is a heterocyclic ring which comprises at least one selected from the group consisting of a hydroxyl group, an amine group, an aldehyde group, a carboxyl group, an alkoxy group and a carbonyl group, and has 1 or 2 nitrogen atoms).

6. The etchant composition according to claim 5, wherein in Formula 1 above, Ar has a structure represented by Formula 2 below: 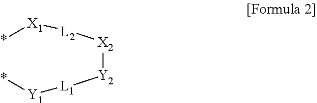
(in Formula 2 above, when L₁ is a direct single bond and Y₁ is NH, Y₂ is a carbonyl group,
when L₁ is a direct double bond and Y₁ is N, Y₂ is C(R₅),
when L₂ is a direct single bond and X₁ is NH or C(R₆R₇), X₂ is a carbonyl group,
when L₂ is a direct double bond and X₁ is N or C(R₈), X₂ is C(R₉),
R₅ and R₉ are each hydrogen, a hydroxyl group, an amine group, an aldehyde group, a carboxyl group, an alkoxy group having 1 to 10 carbon atoms or an alkylcarbonyl group having 2 to 10 carbon atoms,
when Y₂ is C(R₅) and X₂ is C(R₉), one of R₅ and R₉ is hydrogen, a hydroxyl group, an amine group, an aldehyde group, a carboxyl group, an alkoxy group having 1 to 10 carbon atoms or an alkylcarbonyl group having 2 to 10 carbon atoms, and the other is a hydroxyl group, an amine group, an aldehyde group, a carboxyl group, an alkoxy group having 1 to 10 carbon atoms or an alkylcarbonyl group having 2 to 10 carbon atoms, and
R₆ to R₈ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen).

7. The etchant composition according to claim 5, wherein in Formula 1 above, Ar is any one of structures represented by Formulas 3 to 6 below: 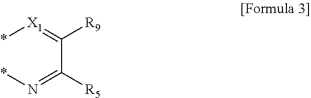
(in Formula 3 above, X₁ is N or C(R₈), R₈ is hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
one of R₅ and R₉ is hydrogen, a hydroxyl group, an amine group, an aldehyde group, a carboxyl group, an alkoxy group having 1 to 10 carbon atoms or an alkylcarbonyl group having 2 to 10 carbon atoms, and the other one is a hydroxyl group, an amine group, an aldehyde group, a carboxyl group, an alkoxy group having 1 to 10 carbon atoms or an alkylcarbonyl group having 2 to 10 carbon atoms) 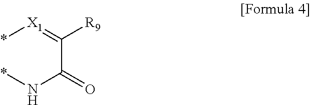
(in Formula 4 above, X₁ is N or C(R₈), R₈ is hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
R₉ is hydrogen, a hydroxyl group, an amine group, an aldehyde group, a carboxyl group, an alkoxy group having 1 to 10 carbon atoms or an alkylcarbonyl group having 2 to 10 carbon atoms) 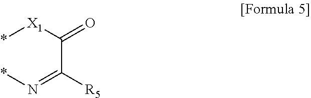
(in Formula 5 above, X₁ is NH or C(R₆R₇), R₆ and R⁷ are each independently hydrogen; an alkyl group having 1 to 10 carbon atoms; an alkyl group having 1 to 10 carbon atoms, which has at least one substituent selected from the group consisting of a hydroxyl group, an amine group, an aldehyde group, a carboxyl group, an alkoxy group having 1 to 10 carbon atoms, an alkylcarbonyl group having 2 to 10 carbon atoms, a nitrous acid group, a nitric acid group, a cyano group and halogen; a hydroxyl group; an amine group; an aldehyde group; a carboxyl group; an alkoxy group having 1 to 10 carbon atoms; a nitrous acid group; a nitric acid group; a cyano group; or halogen, and
R₅ is hydrogen, hydroxyl group, an amine group, an aldehyde group, a carboxyl group, an alkoxy group having 1 to 10 carbon atoms or an alkylcarbonyl group having 2 to 10 carbon atoms)

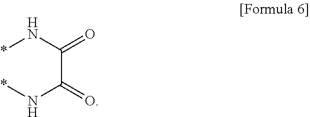 [SMILES: *NC(=O)C(=O)N*]

8. The etchant composition according to claim 1, wherein a content of the nitrogen-containing fused ring compound is 0.01% by weight to 20% by weight based on a total weight of the composition.

9. The etchant composition according to claim 1, wherein a content of the nitrogen-containing fused ring compound is 0.05% by weight to 15% by weight based on a total weight of the composition.

10. The etchant composition according to claim 1, wherein the metal salt comprises a salt of at least one metal selected from the group consisting of a transition metal, a post-transition metal and a metalloid.

11. The etchant composition according to claim 1, wherein a content of the metal salt is 0.0001% by weight to 20% by weight based on a total weight of the composition.

12. The etchant composition according to claim 1, wherein the metal salt comprises a first metal salt which is a salt of at least one metal selected from the group consisting of a transition metal, a post-transition metal and a metalloid, and a second metal salt which is a salt of an alkali metal or an alkaline earth metal.

13. The etchant composition according to claim 12, wherein a content of the first metal salt is 0.0001% by weight to 10% by weight based on a total weight of the composition, and a content of the second metal salt is 0.001% by weight to 18% by weight based on the total weight of the composition.

14. The etchant composition according to claim 1, wherein a ratio of a content of the metal salt to a content of the nitrogen-containing fused ring compound in a total weight of the composition is 0.0005 to 10.

15. The etchant composition according to claim 1, wherein the alkaline compound comprises a nitrogen-based alkaline compound or a metal hydroxide.

16. The etchant composition according to claim 1, wherein a content of the alkaline compound is 0.1% by weight to 20% by weight based on a total weight of the composition.

17. A method of forming a pattern, the method comprising:
forming a silicon-containing film on a substrate;
partially forming a silicon protective film on the silicon-containing film; and
etching the silicon-containing film with the etchant composition according to claim 1.

18. The method of claim 17, wherein the silicon protective film is used as an etching mask.

19. The method of claim 17, wherein the etching of the silicon-containing film comprises etching the silicon-containing film to form a gate pattern.
